(19) United States
(12) Patent Application Publication
(10) Pub. No.: US 2016/0049540 A1
(43) Pub. Date: Feb. 18, 2016

(54) REAR WIDE BAND GAP PASSIVATED PERC SOLAR CELLS

(71) Applicant: Solexel, Inc., Milpitas, CA (US)

(72) Inventors: Pawan Kapur, Burlingame, CA (US); Heather Deshazer, Palo Alto, CA (US); Mohammed Islam, Mountain House, CA (US)

(21) Appl. No.: 14/826,171

(22) Filed: Aug. 13, 2015

Related U.S. Application Data
(60) Provisional application No. 62/037,094, filed on Aug. 13, 2014.

(51) Int. Cl. H01L 31/068; H01L 31/036; H01L 31/0224; H01L 31/028; H01L 31/0216

(52) U.S. Cl. CPC H01L 31/068; H01L 31/028; H01L 31/02167; H01L 31/022441; H01L 31/036

(57) ABSTRACT

A photovoltaic solar cell comprises a light absorbing layer of n-type crystalline silicon. An emitter layer is on the front side of the n-type crystalline silicon. A front passivation layer physically contacts the emitter layer. A front metal contact is on the front passivation layer and contacts the emitter layer. A back layer of wide bandgap semiconductor physically contacts a back side of the n-type crystalline silicon layer. A back metal contact physically contacts the wide bandgap semiconductor layer.

### CROSS-REFERENCE TO RELATED APPLICATIONS

This application claims the benefit of U.S. provisional patent application 62/037,094 filed on Aug. 13, 2014, which is hereby incorporated by reference in its entirety.

### FIELD OF THE INVENTION

The present disclosure relates in general to the fields of solar cells, and more particularly to wide band gap passivation solar cell structure.

### BACKGROUND

Passivated emitter solar cells PESC, passivated emitter rear cells PERC, and passivated emitter rear locally diffused PERL solar cells are some of most commonly used cell architectures in the solar industry. FIGS. 1A, 1B, and 1C show schematic diagram for PESC, PERC, and PERL solar cells, respectively. As may be noted in FIGS. 1A, 1B, and 1C, PERL solar cells may be more complicated than PERC and PESC cells; however, more complicated structures may also be capable of providing higher efficiency. Traditionally, the solar industry has been extremely conservative to move to complicated structures because of rigid cost controls. However, the recent push for higher efficiency has spurred the trend to migrate from PESC to PERC and to PERL. In the highest efficiency PERL design (a special case of PERC), most of the rear surface is passivated by a high quality passivation (traditionally SiO₂ and more recently a combination of Al₂O₃ and SiN) and contact areas are opened in the passivation to touch the metal and draw current. In the case of PERL, these areas are further shielded from metal recombination by providing a localized heavy doping of the same type as the substrate, known as back surface field or a localize BSF. Providing extra shielding of metal recombination and providing passivation requires additional process steps and high quality metal recombination shielding is challenging to attain.

Many industrial solar cells have been based on a p-type substrate. For example, it may be easier to make a PERL cell on p-type substrate because aluminum Al, a commonly used material which serves as solar cell metal, may be fired to make it serve as the p++ localized dopant at the same time. However, recently, there is also a push to move to n-type substrates because of much higher efficiency and lifetimes (without or minimal light induced degradation LID) on these substrates. Making a PERL cell may add more complexity on an n-type substrate as the localized BSF has to be of n++ polarity which cannot necessarily be formed using backside Al metal.

In addition to the aforementioned architectural and substrate type migrations toward higher efficiency, on the front side of the solar cell the industry is steadily moving toward another high efficiency element in a selective emitter structure. Once again, as previously noted, the trade-off for higher efficiency may be the addition of more process steps and cost.

### BRIEF SUMMARY OF THE INVENTION

Therefore, a need has arisen for a solar cell structure having improved efficiency and reduced fabrication complexity. In accordance with the disclosed subject matter, rear wide band gap passivated—passivated emitter rear cells are provided which may substantially eliminate or reduce disadvantages and deficiencies associated with previously developed solar cell structures.

According to one aspect of the disclosed subject matter, a photovoltaic solar cell comprises a light absorbing layer of n-type crystalline silicon is provided. An emitter layer is on the front side of the n-type crystalline silicon. A front passivation layer physically contacts the emitter layer. A front metal contact is on the front passivation layer and contacts the emitter layer. A back layer of wide bandgap semiconductor physically contacts a back side of the n-type crystalline silicon layer. A back metal contact physically contacts the wide bandgap semiconductor layer.

These and other aspects of the disclosed subject matter, as well as additional novel features, will be apparent from the description provided herein. The intent of this summary is not to be a comprehensive description of the claimed subject matter, but rather to provide a short overview of some of the subject matter's functionality. Other systems, methods, features and advantages here provided will become apparent to one with skill in the art upon examination of the following FIGUREs and detailed description. It is intended that all such additional systems, methods, features and advantages that are included within this description, be within the scope of any claims.

### BRIEF DESCRIPTION OF THE DRAWINGS

The features, natures, and advantages of the disclosed subject matter may become more apparent from the detailed description set forth below when taken in conjunction with the drawings in which like reference numerals indicate like features and wherein:

FIGS. 1A, 1B, and 1C show schematic diagram for PESC, PERC, and PERL solar cells, respectively;

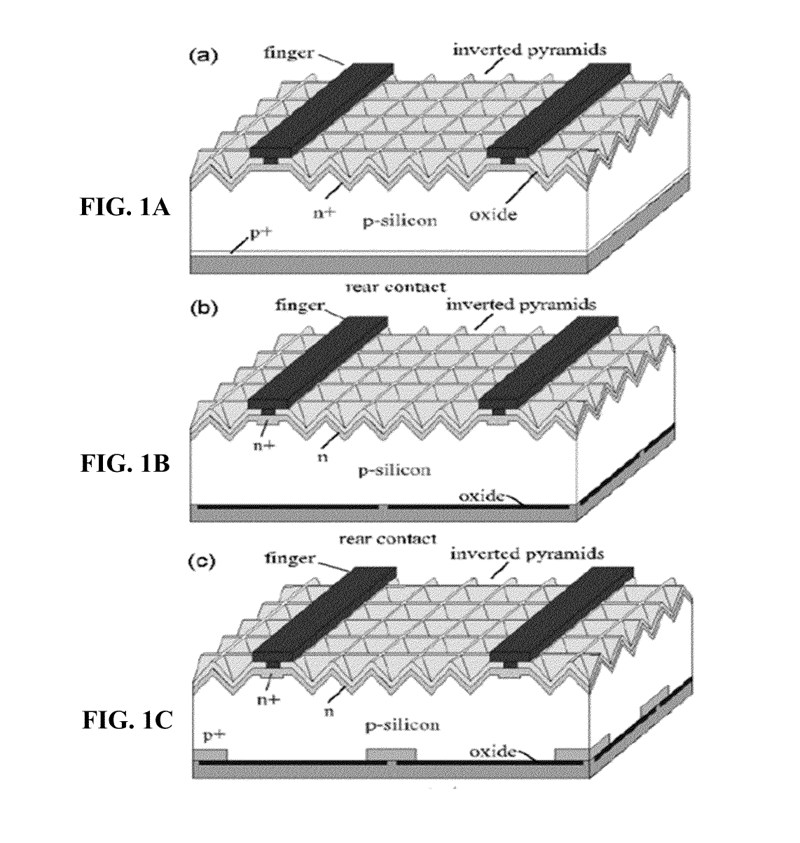

FIG. 2 is a cross-sectional diagram showing a high-level RGP-PERC cross-section using an n-type substrate having blanket back metal; and

FIG. 3 is a cross-sectional diagram showing a high-level RGP-PERC cross-section using an n-type substrate having patterned back metal.

### DETAILED DESCRIPTION

The following description is not to be taken in a limiting sense, but is made for the purpose of describing the general principles of the present disclosure. The scope of the present disclosure should be determined with reference to the claims. Exemplary embodiments of the present disclosure are illustrated in the drawings, like aspects and identifiers being used to refer to like and corresponding parts of the various drawings.

And although the present disclosure is described with reference to specific embodiments and components, one skilled in the art could apply the principles discussed herein to other solar cell structures and materials (e.g., mono crystalline silicon or multi-crystalline silicon), fabrication processes (e.g., various deposition methods and materials such as metallization materials), as well as alternative technical areas and/or embodiments without undue experimentation.

Rear Wide Band Gap Passivated-Passivated Emitter Rear Cells PERC, referred to as RGP-PERC herein, structures and fabrication solutions are provided. The solar cell structure solutions leverage the relative simplicity of the PERC cell to increases cell efficiency while reducing the number of fabrication process steps—in other words the solutions provided both reduce the complexity and improve the efficiency of the standard PERC cell. RGP-PERC not only allows for cell efficiency much higher than a standard PERC cell, RGP-PERC also allows for cell efficiency higher than the more complex, expensive, and traditionally higher efficiency PERL cell architecture—in other words the innovative solution outlined in this document allows solar cells to achieve performance better than that possible by PERL, yet at a substantially reduced number of process steps.

The present application provides a wide bandgap rear passivation which provides not only high quality passivation to silicon, but at the same time provides superior contact to the right type of carriers thus obviating the need of patterning dielectrics and doping areas in the back as it relies on blanket depositions of the film. The wide band gap semiconductor passivation in the back is different material/film for p-type and n-type substrate.

Additionally, high quality solar cell front (frontside) passivation and doping is provided which may further reduce fabrication process steps. Forming doped Al₂O₃ on the cell frontside (e.g., doped Al₂O₃ deposited using atmospheric pressure chemical vapor deposition APCVD) provides superior passivation and also provides a dopant source (for n-type solar cell having a boron based emitter) thus further reducing fabrication process steps.

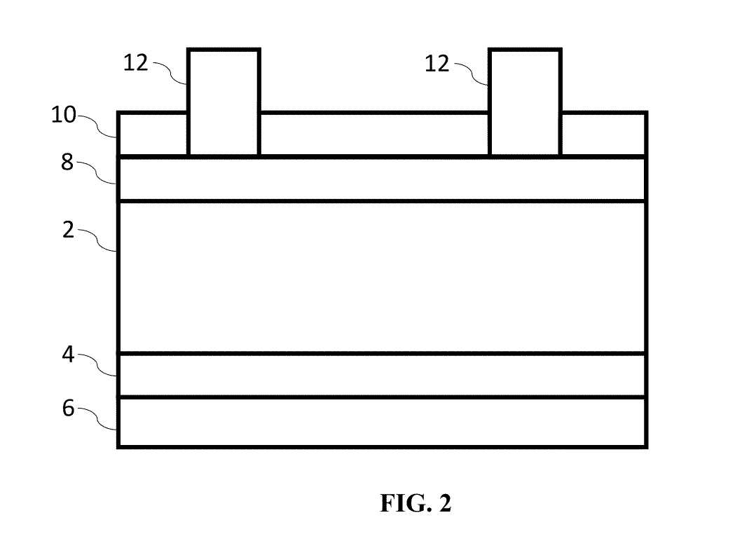

FIG. 2 is a cross-sectional diagram showing a high-level RGP-PERC cross-section using an n-type substrate having blanket back metal. N-type substrate 2 has a front side emitter layer 8 and front side passivation layer or stack 10 (e.g., Al₂O₃). Front metal 12 contact front side emitter layer 8 through front side passivation layer or stack 10. Rear (or back) wide band gap layer or stack 4 (e.g., TiOₓ) is on the rear (or back) of n-type substrate 2. Blanket back metal 6 is on wide band gap layer or stack 4.

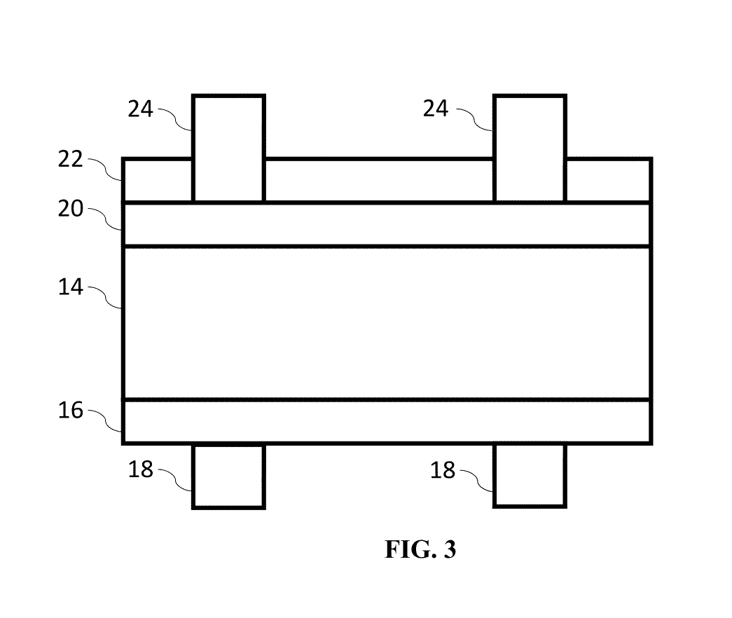

FIG. 3 is a cross-sectional diagram showing a high-level RGP-PERC cross-section using an n-type substrate having patterned back metal. N-type substrate 14 has a front side emitter layer 20 and front side passivation layer or stack 22 (e.g., Al₂O₃). Front metal 24 contact front side emitter layer 20 through front side passivation layer or stack 22. Rear (or back) wide band gap layer or stack 16 (e.g., TiOₓ) is on the rear (or back) of n-type substrate 14. Patterned back metal 18 is on wide band gap layer or stack 16.

The device is possible for both n and p-type silicon substrates. A defining characteristic of the RGP-PERC structure is that it is passivated in the back/rear (non-sunnyside) of the silicon semiconductor using a single wide band gap semiconductor/dielectric or a multi-layer dielectric stack which consists of a wide bandgap semiconductor. This is followed by a suitable metal on the back which may be either blanket (as shown in FIG. 2) or patterned (as shown in FIG. 2). Patterned metal allows for a bifacial solar cell implementation by letting the light through.

For example, in consideration of other factors such as cell structure and fabrication, the rear passivating wide band gap semiconductor/dielectric of the RGP-PERC should satisfy the following three important properties: it should allow the passing of the suitable photo carrier (electrons for n-type and holes for p-type) with minimal contact resistance; it should be a high quality passivation layer with low surface recombination velocity (e.g., a surface recombination velocity SRV less than 20 cm/s); it should present a large and effective barrier for the other photo carrier which is not supposed to go to the rear contact (holes for n-type and electrons for p-type semiconductor).

The RGP-PERC using an n-type substrate may have a wide band gap semiconductor such as titanium oxide TiOx followed by metal on the rear side. This allows the rear stack to be simple while at the same time, because the surface passivation is excellent, hole rejection is superior, and contact resistance to electrons is relatively low, the stack provides a relatively high performance from the stand point of Voc and FF. Note, in a conventional traditional solar cell scheme this type of performance for n-type substrates would be accomplished with a PERL design requiring complex steps (for example, laser fired doping) to create heavy n+ doping under the metal on the rear side while using passivation, such as Al₂O₃+SiN, everywhere else on the cell rear side. Not only is this conventional traditional solar cell scheme more cumbersome, the quality of the passivation under the contact with n+ is inferior to that created using TiOₓ.

It should be noted that TiOₓ is an example of a wide band gap material that may be used for this purpose. In general, a single or multi-layer stack (such as, but not limited to, Al₂O₃+TiOₓ or Al₂O₃+ZnO or any combinations) which satisfies the properties following may be used to form RGP-PERC. Key properties for this rear single or multi-layer material stack are: there should be at least one wide bandgap material which creates a large band offset with holes; the stack creates reasonably good passivation to n-type silicon (e.g., SRV less than 200 cm/s); and, the stack gives reasonable contact resistance to electrons.

In a specific and particularly advantageous embodiment for an n-type silicon PERC, the rear wide band gap semiconductor material is titanium oxide TiOₓ deposited using atomic layer deposition (ALD) which serves as an n-doped wide bandgap semiconductor. Alternative deposition techniques such as physical vapor deposition PVD of TiOₓ may also be suitable if the qualities of the deposited film may be similar to those obtained using ALD. The TiOₓ may be annealed at a temperature in the range of 375 to 450° C. either in N₂ or in a forming gas anneal FGA environment (e.g., 400° C. in FGA) to activate it. The bandgap of TiOₓ is approximately 3.2 eV with majority of the band discontinuity in the valence band with silicon (e.g., approximately 2.1 eV). The conduction band of the TiOₓ tends to line up with the conduction band of silicon. This band alignment presents an excellent low contact resistance flow of carriers for electrons (superior ohmic contact) and a large barrier of approximately 2.1 eV to holes. This large barrier to holes serves as a superior rejection of the holes from the back side base. In addition, ALD deposited TiOₓ has the property of being an excellent passivation, for example providing SRV less than 50 cm/s while being relatively thin (e.g., having a thickness less than 5 nm). The relative thin thickness is also an attribute provides the aforementioned low contact resistance. Thus, TiOₓ satisfies the aforementioned properties and attributes of an RGP-PERC single or multi-layer material rear stack.

For TiOₓ, the cell backside metal may be for example either aluminum, titanium by itself or followed by another metal such as aluminum to increase conductivity. The addition of TiOₓ wide bandgap semiconductor unpins the Fermi level of the metal and raises it close to the charge neutrality level CNL of TiOₓ which itself is close to the conduction band of silicon. This substantially lowers the barrier for electrons to flow between metal and silicon.

Alternatively nickel may be used as a backside metal. Although, nickel's vacuum workfunction is close to the valence band of silicon, it is likely that when deposited on top of a material like TiOₓ, nickel's workfunction gets pulled toward the CNL of TiOₓ which is near the conduction band of silicon—thus providing a lower barrier for electrons. Nickel as a backside may be advantageous as there are relatively easy patterned deposition schemes available with nickel (e.g., nickel deposition using ink jet).

In another embodiment, a rear wide band gap semiconductor/dielectric (and passivation) may be Al₂O₃, for example an atomic layer deposited ALD Al₂O₃. Alternatively Al₂O₃ deposition techniques such as metal organic chemical vapor deposition MOCVD may be used. Because Al₂O₃ is a true insulator, it is imperative that an Al₂O₃ layer be thin (e.g., having a thickness less than 3 nm) to ensure that the contact resistance may be low because of tunneling. Al₂O₃ also serves as an excellent passivation for n-type silicon. A tradeoff with Al₂O₃ is that as it gets thinner its passivation quality reduces. However, there is a possibility of an optimization with respect to Al₂O₃ thickness such that both passivation and contact resistance are sufficient for RGP-PERC.

In yet another embodiment of the RGP-PERC, the back side deposited wide bandgap semiconductor/dielectric may be a bilayer of Al₂O₃ and TiOₓ. This bilayer having a thin Al₂O₃ (e.g., having a thickness less than 2 nm) is characterized is a high quality passivation and contact for electrons. In one possible fabrication process flow, the bilayer may be deposited in-situ inside an ALD reactor. Other bilayers such as Al₂O₃ and ZnO or a combination of Al₂O₃, ZnO, TiO in single or multi-layer formation which meet the properties of hole rejection, passivation quality, and contact resistance may be used as a rear single wide band gap semiconductor/dielectric or a multi-layer dielectric stack.

A bifacial solar cell is compatible with all the rear wide band gap/dielectric embodiments provided herein. Functionally, the back side of the solar cell structure provided may be bifacial to allow the light to be captured from the rear side. This may be accomplished by patterning the backside metal in a grid or other pattern to allow light to come through. Alternatively a patterned metal may be deposited using techniques such as inkjet or screen printing. An additional indium tin oxide ITO layer may be deposited on the solar cell backside as an anti-reflection coating ARC. For example, ITO may be grown using ALD reactor in-situ with the other wide band gap semiconductors or ITO may be sputtered deposited. Silicon nitride SiN may also be used as a solar cell backside ARC.

Relating to the n-type silicon solar cell frontside, solar cells having doped Al₂O₃ which serves the dual function of being a superior passivation and the dopant source for the emitter while allowing for the reduction fabrication process steps are provided. For example, atmospheric pressure chemical vapor deposition APCVD deposited Al₂O₃ despite being driven at a high temperature retains its passivation quality yielding positive Jos on boron emitter down to less than 20 fA/cm². Additionally, the Jo values are found to remain low with the anneal APCVD Al₂O₃ for lower sheet resistivity (rho) emitters down to 50 ohms/sq. Thus providing a high performance without necessarily going to a selective emitter process, thus saving additional process steps.

Front side options for combination with the aforementioned backside options of an RGP-PERC include a standard PERC non-selective emitter and selective emitter and non-selective emitter option using APCVD doped Al₂O₃. Front side embodiments which may be used with the rear side stack include, but are not limited to: Al₂O₃ selective emitter, non-selective emitter, APCVD Al₂O₃ emitter, and non Al₂O₃ standard stacks with SiN. Note, a class of front side possibilities include options where the boron, p+ emitter is passivated using Al₂O₃ (followed by an ARC in the form of SiN or ITO) are used in combination with the RGP-PERC rear side. Another class includes SiN or a thin Sift layer followed by SiN used for this purpose. With both of these options, either selective or non-selective emitter options are possible.

Two manufacturing solutions for an Al₂O₃ boron passivated front side for selective and non-selective emitter are provided. These fabrication solution options allow for reducing manufacturing steps and when taken in conjunction with the rear side fabrication solution options provided herein dramatically reduce the processing steps and cost for manufacturing an RGP-PERC solar cell. An Al₂O₃ boron passivated front side is currently viable with an n-type substrate as it is applicable for a boron doped emitter.

Inventive aspects pivot on the fact that an APCVD doped Al₂O₃ is used as both the passivation and the dopant source. Al₂O₃ is doped with boron and is initially deposited using APCVD. It is then annealed at a high temperature (e.g., a temperature in the range of 950 to 1100° C.) to drive the boron into silicon and form an emitter. Conventional traditional wisdom is that since Al₂O₃ will start to crystallize at these temperatures, the passivation quality may deteriorate thus requiring the Al₂O₃ to be stripped and a fresh Al₂O₃ deposited. However, an optimal anneal temperature is used where despite Al₂O₃ crystallizing, its passivation quality remains relatively superior thus obviating the need for stripping it. Passivation quality has been measured to have a Jo of less than 15 fA/cm². The mechanism is thought to be related to the interfacial layer. APCVD deposited interfacial layer becomes richer in Si as it approaches silicon. The silicon richness allows the interfacial layer to not crystallize during anneal and thus retain its passivation qualities. This film may also be used as an adequate ARC when an adjusted thickness of SiN is formed on top.

Using these properties, a non-selective emitter front side may fabricated simply by using the following steps. Note the sequence may be altered when integrated with RGP-PERC fabrication as described below.

1. APCVD boron doped Al₂O₃

2. Anneal at an optimal temperature (950 to 1100° C.) in N2 environment

3. SiN deposition

4. Laser ablation using pico-second laser

5. Metallization (screen printed or PVD)

If appropriate metallization paste is used, the laser opening can be eliminated and paste can be fired through the SiN/Al₂O₃ stack thus reducing the process flow above to four steps.

While the above non-selective emitter may be expected to be superior as compared to a conventional non-selective emitter because of the ability for Al₂O₃ to passivate boron emitter with a low Jo despite the doping concentration increasing, if selective emitter may be fabricated, for example, with the following modification to the process outlined above.
1. APCVD lightly boron doped Al₂O₃
2. Laser open areas where there is heavily doped emitter
3. APCVD heavy boron doped Al₂O₃
4. Anneal at an optimal temperature (950 to 1100° C.) in N2 environment
5. SiN deposition (thickness of SiN adjusted to provide high quality ARC along with the already present Al₂O₃)
6. Laser ablation using pico second laser OR skip if suitable firing paste is used
7. Metallization (screen printed or PVD)

From device point of view, whenever non-selective emitter is used for cost reasons as compared to a selective emitter, the following trade-offs in performance must be considered: Jo of emitter (Voc); Jo of contact recombination (Voc); sheet resistance of the emitter (FF); contact resistance of the emitter (FF); and, blue response of the cell (Jsc). Out of the these five device factors, Jo of contact recombination, contact resistance of the emitter, and sheet resistance of the emitter prefer heavier doping (smaller sheet rho), while Jo of emitter and blue reasons of the cell prefer light doping (higher sheet rho). With a selective emitter and by having an option of putting a heavier doping under the contact and a lighter doping in the emitter passivation areas, all five parameters may be optimized. Non-selective emitters may not have this option.

However, going to Al₂O₃ with APCVD, the emitter Jo may remain despite emitter sheet resistance as low as 50-70 ohms/sq. This helps expand the process window for optimization without a selective emitter. With a non-selective emitter and APCVD Al₂O₃, by going to lower sheet resistivity (rho), the listed parameters outside of blue response above are addressed while the blue response needs to be optimized. Thus, APCVD doped Al₂O₃ with non-selective emitter for the PERC cell not only reduces the number of process steps compared to a non-selective emitter standard PERC but also may provide performance approaching that of a selective emitter.

In the case of a p-type silicon solar cell RGP-PERC, nickel oxide NiO may be used for the rear wide bandgap semiconductor/dielectric and Al₂O₃ plus NiO for the front side structure.

Representative exemplary fabrication process flows are provided below organized by relevancy to n-type silicon. N-type silicon fabrication process flows may be categorized according to the following characteristics: whether the emitter is passivated by Al₂O₃+SiN or only SiN; whether the device has a selective emitter; whether the device is bifacial or unifacial; and, the metallization strategy.

Relating to metallization strategy, exemplary backside metallization fabrication options and material choice for an RGP-PERC with n-type substrate include PVD of aluminum, titanium, or titanium plus aluminum or nickel inkjet deposition. Exemplary frontside metallization fabrication options and material choice for an RGP-PERC with n-type substrate may be characterized the use of laser processing. For example, if suitable metallization paste is used and no laser opening of the frontside layer or stack (e.g., Al₂O₃) is used on the front then aluminum paste may be screen printed and fired. If laser ablation is used to open the frontside layer or stack, the following example metals and deposition methods may be performed: a patterned screen print of aluminum; patterned PVD of aluminum, copper, titanium, or nickel; or, patterned metal inkjet of nickel.

Subsequently, to increase conductivity, additional metal may be formed on top of already patterned metal. Whether or not laser is used, the metal may be built up for example by screen printing silver or plating copper on the previously formed front side metal.

Relating to the backside metal choice, it may be advantageous that the selected metal for use alongside TiOₓ has a workfunction which is closer to that which aligns with the conduction band of silicon. Hence, Al (4.1 eV) and Ti (˜4.3 eV) may be considered ideal materials for this purpose. However, Ni may also be used albeit with a slightly higher but acceptable contact resistance. For example, when TiOₓ is inserted between silicon and the metal, the work function of the metal tends to gravitated toward the charge neutrality level (CNL) of TiOₓ independent of the vacuum work function of the metal. The CNL of TiOₓ is relatively close to the conduction band of silicon, hence despite that nickel's vacuum workfunction is close to the valence band of silicon, nickel's workfunction tends to approach the conduction band of silicon when on top of TiOₓ. In addition to the above listed deposition techniques for the backside (e.g., screen printing), other suitable deposition techniques which may provide direct patterned metallization deposition or blanket metallization deposition and subsequent metallization patterning are implicitly included.

For n-type substrates, front metal makes contact to the boron doped emitter. Thus front side metal material should be selected such that it makes high quality contact to p-type boron doping, for example Al, Ni, and Ti. In cases where there is no explicit opening of the frontside layer or stack (e.g., Al₂O₃), the metal may need to be fired (e.g., using standard paste screen print/fire sequence with a fritted paste or using a laser).

For the case where an explicit contact is opened using a laser, similar metal types are possible including materials such as Al, Ti, and Ni. However, in this case there is a larger availability of deposition techniques as the metal need not be fired and is in direct contact with the emitter. In an advantageous fabrication process, a patterned seed layer is first deposited (e.g., a patterned see layer deposited using techniques such as inkjetting of, for example, nickel, or direct patterned screen printing of, for example, aluminum). Subsequently, additional metal may be deposited, for example, using screen printing of silver or plating to dramatically increase the conductivity to levels less than 5 ohm/sq sheet resistance to allow single digit metal coverage (to obtain high Jsc).

The following tables are provided as descriptive process flow examples for making an RGP-PERC. The process flows provided herein are representative flows serving as examples and should not be interpreted in a limited sense. Tables 1 and 2 show representative fabrication flows for making an RGP-PERC on n-type silicon without an explicit frontside passivation opening process.

TABLE 1
Metal screen print on front and back. Should use aluminum paste
on the back which does not go through TiOₓ at the temperature
the front past is fired through SiNₓ.

| | |
|---|---|
| 1 | Single side Texture |
| 2 | APCVD B Doped Al2O3 on the front side |
| 3 | Anneal to Form the emitter on the front |
| 4 | ALD TiO2 Backside after surface clean |
| 5 | PECVD SiNx Deposition Frontside |
| 6 | FRONT: Al Screen Print/Fire + Ag screen print/fire to increase |
| | conductivity, BACK: Al screen print |

TABLE 2
Metal screen print on front and metal PVD on back.

| | |
|---|---|
| 1 | Single side Texture |
| 2 | APCVD B Doped Al2O3 on the front side |
| 3 | Anneal to Form the emitter on the front |
| 4 | ALD TiO2 Backside after surface clean |
| 5 | PECVD SiNx Deposition Frontside |
| 6 | FRONT: Al Screen Print/Fire + Ag screen print/fire to increase |
| | conductivity |
| 7 | AL PVD blanket on the back |

Tables 3 through 8 show representative fabrication flows for making an RGP-PERC on n-type silicon with laser opening and various metallization options and no selective emitter and Al₂O₃ passivated emitter.

TABLE 3
Laser open, metal screen print on front and metal PVD on back.

| | |
|---|---|
| 1 | Single side Texture |
| 2 | APCVD B Doped Al2O3 on the front side |
| 3 | Anneal to Form the emitter on the front |
| 4 | ALD TiO2 Backside after surface clean |
| 5 | PECVD SiNx Deposition Frontside |
| 6 | Laser based contact open on the front |
| 7 | Al + Ag Paste print front |
| 8 | PVD Al on the back |

TABLE 4
Laser open, metal inkjet on front and metal PVD on back.

| | |
|---|---|
| 1 | Single side Texture |
| 2 | APCVD B Doped Al2O3 on the front side |
| 3 | Anneal to Form the emitter on the front |
| 4 | ALD TiO2 Backside after surface clean |
| 5 | PECVD SiNx Deposition Frontside |
| 6 | Laser based contact open on the front |
| 7 | PVD Al on the back |
| 8 | Inkjet Ni on the front (Cu Plating or Ag Screen print on top) |

TABLE 5
Laser open, metal inkjet on front and metal inkjet on back.

| | |
|---|---|
| 1 | Single side Texture |
| 2 | APCVD B Doped Al2O3 on the front side |
| 3 | Anneal to Form the emitter on the front |
| 4 | ALD TiO2 Backside after surface clean |
| 5 | PECVD SiNx Deposition Frontside |
| 6 | Laser based contact open on the front |
| 7 | Inkjet Ni on the front and on the back |
| 8 | Optional Ag print of Cu plating on the front |

TABLE 6
Laser open, metal PVD on front and back. The flow may utilize additional
metal patterning process which may be particularly advantageous if the
current in the front may be reduced.

| | |
|---|---|
| 1 | Single side Texture |
| 2 | APCVD B Doped Al2O3 on the front side |
| 3 | Anneal to Form the emitter on the front |
| 4 | ALD TiO2 Backside after surface clean |
| 5 | PECVD SiNx Deposition Frontside |
| 6 | Laser based contact open on the front |
| 7 | Patterned PVD Al + screen print Ag (if necessary) |
| 8 | PVD Al on the back |

TABLE 7
Laser open, metal PVD on front and metal screen print on back.
The flow may utilize an additional metal patterning process.

| | |
|---|---|
| 1 | Single side Texture |
| 2 | APCVD B Doped Al2O3 on the front side |
| 3 | Anneal to Form the emitter on the front |
| 4 | ALD TiO2 Backside after surface clean |
| 5 | PECVD SiNx Deposition Frontside |
| 6 | Laser based contact open on the front |
| 7 | Patterned PVD Al + screen print Ag (if necessary) |
| 8 | Screen print on back and fire |

TABLE 8
Laser open, metal screen print on front and back.

| | |
|---|---|
| 1 | Single side Texture |
| 2 | APCVD B Doped Al2O3 on the front side |
| 3 | Anneal to Form the emitter on the front |
| 4 | ALD TiO2 Backside after surface clean |
| 5 | PECVD SiNx Deposition Frontside |
| 6 | Laser based contact open on the front |
| 7 | Al Paste print front (non-fritted), Al paste print back (non-fritted), |
| | Cofire, Additional SP/fire Ag on Front |

Other deposition techniques and adjusted process sequence may be possible and apparent by those skilled in the art. For example instead of an ARC using PECVD SiN ARC an ITO based ARC using either PVD deposition or ALD deposition may be utilized.

Several fabrication steps in the process flows provided are not explicitly mentioned. For example, these may include edge isolation, saw damage removal, and an anneal of TiO₂ film after ALD if the SiN deposition temperature does not anneal TiO₂ film. If a TiO₂ film anneal is required, it may be performed in an FGA or N62 environment at temperatures in the range of 375 to 450° C. (e.g., 425° C. in FGA environment).

Advantageous aspects of the metallization options provided herein may include cases where the back metal is PVD Al, PVD Ti/Al, or inkjet Ni (if the contact resistance is found to be acceptable with Ni on TiOₓ), and cases where the front metallization fabrication uses contact opening process to open a contact to p-doped silicon through the front passivation using laser. Subsequently, either Al paste, patterned PVD, or Ni inkjet followed by either Ag screen print or plating may be used (only if conductivity requirements are high) to form the front metal. Al paste which can be fired in temperature ranges between 510 to 560° C. and makes an excellent contact to p-type silicon down to 180 ohms/sq sheet resistance may be used. The conductivity of this Al paste may be brought down to 50 uohm-cm. This Al paste may serve as an excellent patterned metal seed along with patterned nickel inkjet to make high quality contact to the silicon emitter. Subsequently, metal for increased conductivity may be formed using techniques such as, but not limited to Ag screen print or Cu plating.

Tables 9 through 14 show representative fabrication flows for making an RGP-PERC on n-type silicon where the emitter doping layer is stripped and a new Al₂O₃ layer is deposited. While the re-deposited Al₂O₃ may be advantageously deposited using ALD, other techniques such as PECVD Al₂O₃ followed by SiN or APCVD Al₂O₃ may also be used. Note, that if ALD Al₂O₃ is performed, it is desirable that the Al₂O₃ thickness be greater than 10 nm to provide high quality passivation. Optionally, ALD Al₂O₃ and ITO may be performed in-situ in the ALD reactor. ITO may form the ARC and obviate the need for SiN.

Table 9 shows a representative fabrication flow with Al₂O₃ and SiN passivation stack on the cell front side and advantageous metallization fabrication of Al paste print followed by Ag paste print on the front side after opening the contact. Al is formed by PVD on the cell back side on top of TiOₓ. Alternatively, as previously described, Ni inkjet may be used as a seed layer followed by plating or screen print of Ag.

TABLE 9
Laser open, metal screen print on front and metal PVD on back.

| | |
|---|---|
| 1 | Single side Texture |
| 2 | APCVD Boron doped oxide (BSG) or boron doped AL2O3 |
| 3 | Anneal to Form the emitter on the front |
| 4 | Etch away all APCVD |
| 5 | PECVD Al2O3 and SIN on the front |
| 6 | ALD BACK TiOx by itself (unifacial) or TiOx/ITO (ITO if bifacial) |
| 7 | Laser based contact open on the front |
| 8 | Al + Ag Paste print front |
| 9 | AL PVD blanket on the back (patterned if bifacial) |

Tables 10 through 14 shows representative fabrication flows with a stripped dopant source and using ITO ARC instead of SiN ARC and where the ITO is deposited in-situ in the ALD reactor after Al₂O₃. Fabrication flows of Tables 10 through 14 show Al₂O₃ passivated emitter and non-selective emitter. In the case of complexity of firing the metal paste through ITO, the contact may be opened (e.g., laser opening) and SiN may be used as ARC. A parallel set of process flows where the ARC is SIN instead of ITO may be obtained by the person skilled in the art.

TABLE 10
Metal screen print on front and metal PVD on back.

| | |
|---|---|
| 1 | Single sided Texture |
| 2 | APCVD Boron doped oxide (BSG) or boron doped AL2O3 |
| 3 | Anneal to Form the emitter on the front |
| 4 | Etch away all APCVD |
| 5 | ALD front Al2O3/ITO and back TiOx/ITO (ITO if bifacial) |
| 6 | Al + Ag Screen Print/Fire on Front (Al for contact resistance) |
| 7 | AL PVD blanket on the back (patterned if bifacial) |

TABLE 11
Laser open, metal screen print on front and metal PVD on back.

| | |
|---|---|
| 1 | Single side Texture |
| 2 | APCVD Boron doped oxide (BSG) or boron doped AL2O3 |
| 3 | Anneal to Form the emitter on the front |
| 4 | Etch away all APCVD |
| 5 | ALD front Al2O3/ITO and back TiOx/ITO (ITO if bifacial) |
| 6 | Laser based contact open on the front |
| 7 | Al + Ag Paste print front (Al for the contact resistance) |
| 8 | AL PVD blanket on the back (patterned if bifacial) |

TABLE 12
Laser open, metal PVD on front and back.

| | |
|---|---|
| 1 | Single sided Texture |
| 2 | APCVD Boron doped oxide (BSG) or boron doped AL2O3 |
| 3 | Anneal to Form the emitter on the front |
| 4 | Etch away all APCVD |
| 5 | ALD front Al2O3/ITO and back TiOx/ITO (ITO if bifacial) |
| 6 | Laser based contact open on the front |
| 7 | Patterned PVD Al on the front + Ag screen print (if necessary) |
| 8 | AL PVD blanket on the back (patterned if Bifacial) |

TABLE 13
Laser open, metal inkjet on front and metal PVD on back.

| | |
|---|---|
| 1 | Single sided Texture |
| 2 | APCVD Boron doped oxide (BSG) or boron doped AL2O3 |
| 3 | Anneal to Form the emitter on the front |
| 4 | Etch away all APCVD |
| 5 | ALD front Al2O3/ITO and back TiOx/ITO (ITO if bifacial) |
| 6 | Laser based contact open on the front |
| 7 | AL PVD blanket on the back (patterned if bifacial) |
| 8 | Inkjet Ni on the front + Cu plating (if required) |

TABLE 14
Laser open, metal inkjet on front and back.

| | |
|---|---|
| 1 | Single sided Texture |
| 2 | APCVD Boron doped oxide (BSG) or boron doped AL2O3 |
| 3 | Anneal to Form the emitter on the front |
| 4 | Etch away all APCVD |
| 5 | ALD front Al2O3/ITO and back TiOx/ITO (ITO if bifacial) |
| 6 | Laser based contact open on the front |
| 7 | Inkjet patterned Ni on the front + and Ni on the |
| | back + Cu plating (if required) |

Various exemplary fabrication flows provided above (particularly those involving ITO). A bifacial cell RGP-PERC is similar to a unifacial RGP-PERC with two noted modifications. A bifacial RGP-PERC may benefit from an ARC on the back side which for example, in one advantageous embodiment may be grown in-situ with the TiOₓ in the back in the same ALD reactor. Alternatively, ITO may also be sputtered on top of TiOₓ. The second noted modification is that the metal in the back should not be blanket but instead patterned so that the light can get through.

Tables 15 through 18 show representative fabrication flows for making a bifacial RGP-PERC on n-type with Al₂O₃ passivated emitter and non-selective emitter (NSE).

TABLE 15
Metal screen print on front and metal PVD on back.

| | |
|---|---|
| 1 | Single sided Texture |
| 2 | APCVD B doped Al2O3 on the front side |
| 3 | Anneal to Form the emitter on the front |
| 4 | ALD TiO2 Backside followed by ALD ITO in the same machine |
| 5 | PECVD SiNx Deposition Frontside |
| 6 | Al Screen Print/Fire on Front |
| 7 | Patterned AL PVD on the back |

TABLE 16
Laser open, metal screen print on front and metal PVD on back.

| | |
|---|---|
| 1 | Single sided Texture |
| 2 | APCVD B doped Al2O3 on the front side |
| 3 | Anneal to Form the emitter on the front |
| 4 | ALD TiO2 Backside followed by ALD ITO in the same machine |
| 5 | PECVD SiNx Deposition Frontside |
| 6 | Laser based contact open on the front |
| | Al Paste print front |
| 7 | Patterned AL PVD on the back |

TABLE 17
Laser open, metal inkjet on front and metal PVD on back.

| | |
|---|---|
| 1 | Single side Texture |
| 2 | APCVD B Doped Al2O3 on the front side |
| 3 | Anneal to Form the emitter on the front |
| 4 | ALD TiO2 Backside followed by ALD ITO in the same machine |
| 5 | PECVD SiNx Deposition Frontside |
| 6 | Laser based contact open on the front |
| 7 | Patterned AL PVD on the back |
| 8 | Inkjet Ni on the front and optional cu plating if required |

TABLE 18
Laser open, metal inkjet on front and back.

| | |
|---|---|
| 1 | Single side Texture |
| 2 | APCVD B Doped Al2O3 on the front side |
| 3 | Anneal to Form the emitter on the front |
| 4 | ALD TiO2 Backside followed by ALD ITO in the same machine |
| 5 | PECVD SiNx Deposition Frontside |
| 6 | Laser based contact open on the front |
| 7 | Inkjet Ni on the front and on the back with an optional cu |
| | plating if required |

Metallization schemes mentioned for the unifacial cell may be applicable also be applicable in the fabrication of a bifacial structure. Additionally, the stripped APCVD AL₂O₃ fabrication processes may also be applicable.

Among other embodiments, the following exemplary embodiments are specifically provided herein.

For a non-bifacial with single dielectric stack (TiOₓ, NiO, and Al₂O₃) specific embodiments include, but are not limited to the following:
A front contact solar cell where the non-sunny (rear) interface consists of silicon, wide-bandgap semiconductor and metal
   a. A front contact silicon solar cell where the silicon is n-doped with a wide band gap semiconductor and metal constitute the rear interface
   b. Where the wideband gap semiconductor such that its conduction band lines up with silicon for n-type solar cell and valence band exhibits a large band discontinuity with silicon's valence band
      i. Where wide bandgap semiconductor provides excellent passivation to silicon
      ii. Where wide band gap semiconductor provides a high rejection barrier for holes
      iii. Where the wide band gap semiconductor is titanium oxide deposited by atomic layer deposition
      iv. Where the wide band gap dielectric is aluminum oxide deposited by atomic layer deposition
   c. Where the metal in the back is blanket and consists of a vacuum workfunction which is close to the conduction band of silicon
      i. Where the metal in the back is aluminum deposited using physical vapor deposition
      ii. Where the metal in the back is Al deposited using screen printing metal paste.
      iii. Where the metal in the back is titanium deposited by various deposition schemes such as ink jet and PVD.
   d. Where the metal in the back is patterned, thus forming a bifacial cell, and consists of a workfunction which is close to the conduction band of silicon,
      i. Where the metal in the back is aluminum deposited using physical vapor deposition
      ii. Where the metal in the back is Al deposited using screen printing metal paste.
      iii. Where the metal in the back is titanium deposited by various deposition schemes.
A front contact silicon solar cell where the silicon is p-doped with a wideband gap semiconductor and metal constitute the rear interface
   i. Where wide bandgap semiconductor provides excellent passivation to p-type silicon
   ii. Where wide bandgap semiconductor provides a high rejection barrier for electrons
   iii. Where the wide bandgap semiconductor is nickel oxide deposited by atomic layer deposition or other means
   iv. Where the wide bandgap dielectric is Al₂O₃ deposited using ALD or other means.
b. Where the metal in the back is blanket and consists of a workfunction which is close to the valence band of Silicon
   i. Where the metal in the back is Ni deposited using physical vapor deposition
   ii. Where the metal in the back is Ni deposited using inkjet.
c. Where the metal in the back is patterned forming a bifacial cell and consists of a workfunction which is close to the valence band of silicon.
   i. Where the metal in the back is Nickel deposited using physical vapor deposition
   ii. Where the metal in the back is Ni deposited using inkjet

For a front contact solar cell where the front (sunny-side) emitter passivation is Al₂O₃ in combination with the rear (non-sunny side) interface consisting of silicon, wide-bandgap semiconductor, and metal
A front contact solar cell where the front Al₂O₃ is deposited using APCVD
A front contact solar cell where the Al₂O₃ which is the passivation also serves as a dopant source for emitter formation
A front contact solar cell, Where the Al₂O₃ is deposited using ALD, APCVD, or PECVD after dopant sources have been stripped.
Where combination of Al₂O₃ and SIN serve as the ARC

A front contact solar cell where both selective and non-selective emitter PERC designs are combined with the non-sunny (rear) interface consisting of silicon, wide-bandgap semiconductor, and metal.

For a non-bifacial structure having a multi-layer dielectric stack:
A front contact solar cell where the non-sunny (rear) interface consists of silicon, a multi-layer dielectric stack including a wide-bandgap semiconductor, and a metal
   a. Where the stack for n-type is Al₂O₃/TiOₓ/Al or Al₂O₃/TiOₓ/Ti
A front contact solar cell where the front (sunny-side) emitter passivation is Al₂O₃ in combination with the rear (non-sunny side) interface consisting of silicon, a multi-layer dielectric stack including a wide-bandgap semiconductor, and a metal.
   a. Where the stack for n-type is Al₂O₃/TiOₓ/Al or Al₂O₃/TiOₓ/Ti
A front contact solar cell where both selective and non-selective emitter PERC designs are combined with the non-sunny (rear) interface consisting of silicon, a multi-layer dielectric stack including a wide-bandgap semiconductor, and metal.
   a. Where the stack for n-type is Al₂O₃/TiOₓ/Al or Al₂O₃/TiOₓ/Ti

For a bifacial structure having a single stack (for n-type and p-type silicon):
A bifacial solar cell (not limited to PERC) where the bifaciality is achieved by growing a wide band gap semiconductor and ITO in-situ in an ALD reactor and using a patterned metal on top.
A bifacial solar cell where the rear side (non-sunny side) stack consists of silicon semi-conductor, a wide bandgap semiconductor/dielectric such as TiOₓ on n-type and NiO on p-type, and Al₂O₃ for both n and p-type, and an optional transparent conducting oxide (TCO) such as ITO, and a patterned metal.
   a. Where the TCO layer on the rear side (non-sunny side) is optional, but the patterned metal is a must.
   b. Where the TCO layer, when present is ITO and is optimized to serve as an ARC.
   c. Where the ITO layer, when present, is deposited in-situ along with the wide bandgap semiconductor in the ALD reactor
   d. Where the ITO layer, when present, is deposited separately using a different deposition scheme such as PVD.
   e. Where the patterned metal is a metal with a vacuum workfunction close to the conduction band edge of silicon for n-type silicon
      i. Where this metal is aluminum deposited using PVD, screen print, or other means
      ii. Where this metal is titanium deposited using PVD
   f. Where the patterned metal is a metal with a vacuum workfunction close to the conduction band edge of silicon for the p-type silicon
      i. Where this metal is nickel deposited using PVD, inkjet, or other means.

A bifacial solar cell where the rear side (non-sunny side) stack consists of silicon semi-conductor, a multi-layer dielectric stack with a wide bandgap semiconductor/dielectric such as TiOₓ on n-type and NiO on p-type along with thin Al₂O₃, and an optional transparent conducting oxide (TCO) such as ITO, and a patterned metal.

The foregoing description of the exemplary embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein.

What is claimed is:

1. A photovoltaic solar cell comprising:
a light absorbing layer of n-type crystalline silicon;
an emitter layer on a front side of said n-type crystalline silicon;
a front passivation layer physically contacting said emitter layer;
a front metal contact on said front passivation layer and contacting said emitter layer;
a back layer of wide bandgap semiconductor physically contacting a back side of the n-type crystalline silicon layer; and
a back metal contact physically contacting the wide bandgap semiconductor layer.
